(19) United States
(12) Patent Application Publication
(10) Pub. No.: US 2023/0038255 A1
(43) Pub. Date: Feb. 9, 2023

(54) DIELECTRIC APPARATUS APPLIED TO BUILDING COMPONENTS AND MANUFACTURING METHOD THEREOF

(71) Applicant: EIKO TECHNO CORPORATION PTE. LTD., SINGAPORE (SG)

(72) Inventor: MING LU, NEW TAIPEI CITY (TW)

(21) Appl. No.: 17/816,172

(22) Filed: Jul. 29, 2022

Related U.S. Application Data
(60) Provisional application No. 63/203,751, filed on Jul. 29, 2021.

(51) Int. Cl. E04B 1/92; H05K 9/00

(52) U.S. Cl. CPC E04B 1/92; H05K 9/0001

(57) ABSTRACT

A dielectric apparatus applied to building components is disclosed for switching the working frequency of the radio signal passing through the building components and increasing the radio signal's transmittance and the transmission bandwidth. The dielectric apparatus includes a structure body, a filler, and a positioning component. The structure body is made of dielectric materials and includes a chamber. Based on different operating frequencies, the chamber may be filled with the filler made by corresponding dielectric materials to change the operating frequency. The range of the dielectric constant value of the materials used in the structure body and the material for filling the chamber is greater than 1 and less than 200000. The positioning component couples the structure body to a building component to form a composite structure to realize the passage of the specific radio frequency signals and to achieve the effect of enhancing the transmittance.

### CROSS-REFERENCE TO RELATED APPLICATION

This application claims priority to and the benefit of, pursuant to 35 U.S.C. § 119, U.S. provisional patent application Ser. No. 63/203,751 filed on Jul. 29, 2021, the disclosure of which is incorporated herein in its entirety by reference.

### BACKGROUND

### 1. Technical Field

The present disclosure relates to a dielectric apparatus for building components and an arrangement method thereof, in which the dielectric apparatus couples a dielectric building component and then switches the operating frequency of a radio frequency signal passing through the building component, so as to increase the signal strength and transmission bandwidth of the operating frequency.

### 2. Description of the Related Art

In order to meet the market demand for high-speed information transmission, the telecommunication industry has already adopted multi-band high-frequency electromagnetic waves to transmit signals. In this development trend, telecommunication companies, network service companies and research entities in various countries conducted field tests and discovered signal transmission quality is significantly affected by building materials and building components because frequency bandwidths up to the high frequency spectrum are used. Even when building materials and building components are made of dielectric materials with low dielectric loss, reflection loss may still occur in certain electromagnetic spectrum due to mismatch between the material itself and the external dielectric constant. In one example in which glass without any coating is used in the air, typical glass would cause 2 dB to 4 dB of reflection loss in the environment of high-frequency communication. This means that 50% of the energy of electromagnetic waves is converted to the reflection loss due to the shielding of the glass during the transmission process. In addition, data protection and privacy have become universally important to the public in the process of communication deregulation. In addition to using methods such as passwords or encrypted transmissions, which are widely used today to protect the acquisition and decryption of transmitted data by unauthorized persons, it has become an important problem to be solved in recent wireless communication to block data or allow others to access the data by satisfying the transmittance of electromagnetic waves of specific frequencies for building components according to the user's needs.

In order to solve the signal attenuation problem caused by the materials and structures using the above-mentioned building components made of dielectric materials, various examples have been studied and may be summarized in certain ways according to different operational mechanisms. An internal antenna, an internal/external antenna containing a lead wire, a dielectric antenna, and a periodic conductive structure are included. The methods of installing the internal antenna, the internal/external antenna containing the lead wire, and the like are widely used in vehicle communication and in a building environment. According to the above scheme, a signal is received through an antenna, the received signal is amplified or not amplified according to the configuration of the system, and the processed signal is transmitted to the outside through a lead wire or an antenna. In some schemes, a dielectric surface is used as an antenna substrate, and an antenna for transmitting and receiving signals is manufactured through a patterned conductive layer. Specific examples may be found in patent documents such as U.S. Pat. Nos. 3,728,732, 4,849,766, 5,083,133, 5,821,904, 5,867,129, 6,121,934, 6,239,758, 6,661,386, 7,091,915, 8,009,107, 9,350,071, EP1343221, EP2581983, CN104685578B and CN105075008. In the periodic metal structure scheme, a periodic metal structure is simply fabricated on a dielectric so that the size of the metal structure is adjusted to generate a phenomenon in which the entire structure selectively transmits an electromagnetic wave of a specific wavelength. Thus, the above periodic metal structure is also called a frequency-selective surface. Related example may be found in patent documents such as JP2004053466, JP2011254482, U.S. Pat. Nos. 4,125,841, 6,730,389, 10,741,928, CN1561559, and CN104269586. However, all of the above-described schemes require a conductive structure for transmitting and receiving an electromagnetic wave signal or filter, and particularly, fail to switch and adjust the electromagnetic spectrum passing through the building components.

### SUMMARY

An object of the present invention is to solve the problems existing in the conventional communication technology described above and provide a dielectric apparatus and an arrangement method thereof to switch the operating frequency, increase the electromagnetic wave transmittance of an existing building component made of a dielectric material, and increase the bandwidth of a radio frequency signal. Since there is no need to fabricate a patterned conductive layer and power and signal contacts are unnecessary, the production can be easily performed, the cost is low, and the installation is conveniently conducted.

One embodiment of the present invention provides a dielectric apparatus for a building component for increasing the transmittance of a radio frequency signal, extending the frequency bandwidth of the radio frequency signal, and switching an operating frequency. The dielectric apparatus includes a structure body, a filler, and a positioning component, wherein the structure body is formed of one or more dielectric materials and includes one or more cavities, in which the chamber may be filled with a filler made of the corresponding dielectric material according to different operating frequencies, and the positioning component couples the structure body to a target component (building component). In the radio frequency signal transmission area, the dielectric material composed of the structure body, the filler and the positioning component has a dielectric constant value in a range of greater than 1 and less than or equal to 200,000. The structure body is coupled to the building component to form a composite structure. The composite structure may lower the reflection loss by allowing a radio frequency signal corresponding to the operating frequency to pass therethrough, and the minimum equivalent diameter of a dielectric structure corresponding to the composite structure at a projection surface of a joint surface through which the radio frequency signals pass is at least ⅛ of the operating wavelength corresponding to the operating frequency.

Preferably, according to the required application, the structure body of the dielectric apparatus may be divided into different blocks to correspond to different operating frequencies. The dielectric material constituting a structure body of each block may use a dielectric material having the same dielectric constant value, and the filler made of the dielectric material in each block may use a dielectric material having the same dielectric constant value. An admittance value of each block is adjusted through the difference in design structure of each block so as to satisfy the requirement of a minimum reflectance corresponding to the operating frequency, and the dielectric constant values of the dielectric materials used to constitute the structure body and the filler are in a range of greater than 1 and less than or equal to 200,000, and the minimum equivalent diameter of a dielectric structure corresponding to the composite structure of each block at a projection surface of a target component surface through which the radio frequency signal passes is at least ⅛ of the operating wavelength corresponding to the operating frequency.

Preferably, according to the required application, the structure body of the dielectric apparatus may be divided into different blocks to correspond to different operating frequencies. The dielectric material constituting a structure body of each block may use a dielectric material having a different dielectric constant value, and the filler made of the dielectric material in each block may use a dielectric material having the same dielectric constant value. An admittance value of each block is adjusted through the difference in material and design structure of each block so as to satisfy the requirement of a minimum reflectance corresponding to the operating frequency, the dielectric constant values of the dielectric materials used to constitute the structure body and the filler are in a range of greater than 1 and less than or equal to 200,000, and the minimum equivalent diameter of a dielectric structure corresponding to the composite structure of each block at a projection surface of a target component surface through which the radio frequency signal passes is at least ⅛ of the operating wavelength corresponding to the operating frequency.

Preferably, according to the required application, the structure body of the dielectric apparatus may be divided into different blocks to correspond to different operating frequencies. The dielectric material constituting a structure body of each block may use a dielectric material having a different dielectric constant value, and the filler made of the dielectric material in each block may select a dielectric material having the different dielectric constant value. An admittance value of each block is adjusted through the difference in material and design structure of each block so as to satisfy the requirement of a minimum reflectance corresponding to the operating frequency, the dielectric constant values of the dielectric materials used to constitute the structure body and the filler are in a range of greater than 1 and less than or equal to 200,000, and the minimum equivalent diameter of a dielectric structure corresponding to the composite structure of each block at a projection surface of a target component surface through which the radio frequency signal passes is at least ⅛ of the operating wavelength corresponding to the operating frequency.

Preferably, the dielectric material of the structure body of each block may further include a multilayer dielectric material structure layer formed of a second or more dielectric materials, and the range of dielectric constant values of dielectric materials constituting the dielectric material layer is greater than 1 and less than or equal to 200,000.

Preferably, the structure body may further include a multilayer dielectric material layer having more than one layer of a dielectric material, and the dielectric constant value of the dielectric material constituting each layer is in the range of greater than 1 and less than or equal to 200,000.

Preferably, the chamber may be arranged on a surface of the structure body.

Preferably, the chamber may be interposed between the structure body and the target component.

Preferably, the chamber may be arranged inside the structure body, but may not come into contact with the target component.

Preferably, the dielectric material constituting the filler may be a solid, and include a solid powder material or a molded filler.

Preferably, the dielectric material constituting the filler may be in a liquid form.

Preferably, the dielectric material constituting the filler may be in a gaseous form.

Preferably, when the dielectric material constituting the filler is in a solid form, the operating frequency may be switched by placing or removing the filler in the chamber.

Preferably, when the dielectric material constituting the filler is a gaseous filler or a liquid fluid filler, the operating frequency may be switched by injecting the dielectric material into the chamber or extracting the dielectric material from the chamber using a fluid pump and a fluid pipe.

Preferably, the positioning component may be formed of a dielectric material, and an equivalent dielectric constant value ranges from greater than 1 to 200,000 or less.

Preferably, the positioning component may be partially interposed between the structure body and the target component.

Preferably, the dielectric apparatus may further include a void area.

Preferably, the void area may be interposed between the structure body and the target component.

Preferably, the void area may be arranged inside the structure body, but may not come into contact with the target component.

According to the embodiments of the present invention, a method for arranging the dielectric apparatus applied to building components are provided to switch the operating frequency of a radio frequency signal passing through a building component and increase the transmittance and transmission bandwidth of the radio frequency signal. The arrangement method includes joining a structure body to a target component by using a positioning component. The structure body is formed of a dielectric material and the structure body includes a chamber, the chamber is filled with a filler formed of a dielectric material, the positioning component is formed of a dielectric material in an area through which a radio frequency signal passes, the range of a dielectric constant value of each dielectric material is greater than 1 and less than or equal to 200,000, the positioning component couples a structure body formed of a dielectric material to a target component, thereby forming a composite structure correspondingly having the operating frequency, and the minimum equivalent diameter of a dielectric structure corresponding to the composite structure at a projection surface of a target component surface through which the radio frequency signals pass is at least ⅛ of the operating wavelength corresponding to the operating frequency.

Preferably, the arrangement method may further include arranging a void area within the dielectric apparatus.

The dielectric apparatus invention and the arrangement method thereof proposed according to the present invention have at least the following advantages: (1) It can be manufactured with a dielectric material with a simple structure and process, so that mass production can be facilitated. (2) External power and signals are not required to be introduced, so that the installation and usage can be simplified and convenient; (3) The operation can be performed without electricity, so that electricity and operating costs can be saved; (4) The dielectric apparatus is not a signal emitting source, so that the potential biological risk due to electromagnetic radiation can be relieved. (5) The use of radio frequency signals of wide bandwidths and multiple frequency bandwidths can be supported; (6) The spectrum can be switched according to user's request.

### BRIEF DESCRIPTION OF THE DRAWINGS

The present disclosure is further described below together with the accompanying drawings and embodiments, in the accompanying drawings:

FIG. 1 shows an admittance diagram according to the related art.

FIGS. 2A and 2B are sectional views each showing the dielectric apparatus according to the embodiment of the present invention.

FIGS. 3A and 3B are sectional views each showing the dielectric apparatus according to the embodiment of the present invention.

FIGS. 4A and 4B are sectional views each showing the dielectric apparatus according to the embodiment of the present invention.

FIGS. 5A and 5B are sectional views each showing the dielectric apparatus according to the embodiment of the present invention.

FIGS. 6A and 6B are sectional views each showing the dielectric apparatus according to the embodiment of the present invention.

FIGS. 7A and 7B are sectional views each showing the dielectric apparatus according to the embodiment of the present invention.

FIGS. 8A and 8B are sectional views each showing the dielectric apparatus according to the embodiment of the present invention.

FIG. 9 is a schematic diagram illustrating that a dielectric apparatus according to the embodiment of the present invention is joined and used with a target component.

FIGS. 10A and 10B are graphs showing a reflectance and a transmittance, respectively, when an electromagnetic wave of 2 GHz to 6 GHz passes through glass having a thickness of 6 mm and a dielectric constant of 7.

FIGS. 11A and 11B are graphs showing the reflectance and the transmittance when electromagnetic waves of 2 GHz to 6 GHz pass through glass having a thickness of 8 mm and a dielectric constant of 7 in various filler states for three cavities in which a dielectric apparatus according to the embodiment of the present invention is coupled thereon.

### DESCRIPTION OF THE PREFERRED EMBODIMENTS

In order to understand the technical features, contents and advantages of the present invention, hereinafter, the present invention will be described using the form of representation of the embodiments in detail with reference to the drawings as follows with reference to the accompanying drawings. However, the drawings are only intended to supplement the specification as a gist, and may not correspond to the actual proportions and exact arrangements after implementation of the present invention. Accordingly, it will be noted that the drawings do not limit the scope of the claims to be actually implemented by the present invention upon interpretation related to the proportions and arrangement of the accompanying drawings.

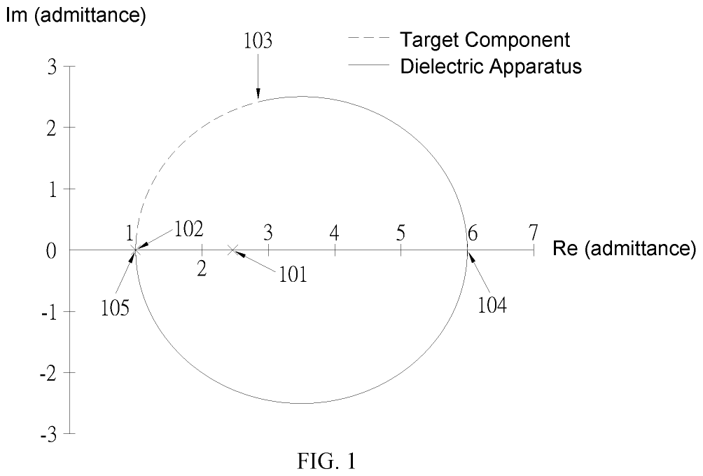

Referring to FIG. 1, it shows an admittance diagram according to the related art. For example, the target component of εₛ=εᵣ=6 (indicated by position 101) is arranged in an environment of εᵣ=1 (indicated by position 102), an admittance value αₛ of the target component shifts from position 102 to position 103 along the circle in a clockwise direction as the thickness of the target component gradually increases from 0 to tₛ. Next, for example, a dielectric apparatus with a structure body formed of a first dielectric material having a dielectric coefficient of εₛ=εᵣ=6 is selected and coupled to the target component to form a composite structure. As the thickness of the apparatus gradually increases from 0 to t₁, the admittance value (αₛ+α₁) of the composite structure would continue to shift clockwise along the circle form position 103 as illustrated in the figure, pass a phase thickness

$$( 2 * n - 1 ) * \frac{π}{2}$$

at position 104 on a real part axis (Re) and cross a phase thickness n*π at position 105 on the real part axis (Re). In other words, t₁ corresponding to the phase thickness n*π becomes the optimum thickness of the apparatus, so that the composite structure would have an improved transmittance in a specific electromagnetic wave spectrum. The value of n in the above two formulas is not a zero but a positive integer. When the multi-layer structure or positioning component is a dielectric and is located in an area through which the radio frequency signals may pass, the compensation analysis method is the same as the above method. In addition, when considering the bandwidth and production process in the actual application situation, an acceptable range of thickness variation may be within +/−25%.

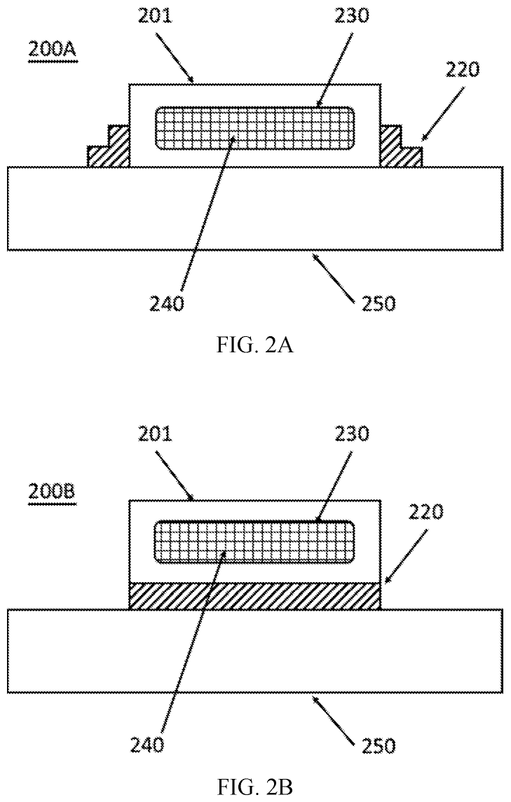

The thickness of the apparatus corresponding to the structure body with a different operating frequency and the dielectric constant of the filler are determined based on the admittance compensation technique shown in FIG. 1. Next, refer to FIGS. 2A and 2B. FIGS. 2A and 2B are sectional views each showing a dielectric structure according to another embodiment of the present invention.

The dielectric apparatus 200A of FIG. 2A includes a structure body 201 and a positioning component 220. The structure body 201 is formed of a first dielectric material, the structure body 201 includes a chamber 230, and a filler 240 formed of a second dielectric material may fill the chamber 230 when the operating spectrum is required to be switched. The range of dielectric constant values of the first dielectric material and the second dielectric material is greater than 1 and less than or equal to 200,000. The structure body is coupled to the target component 250 by using the positioning component 220. In the transmission state of a radio frequency signal having operating frequency off and a corresponding wavelength of k, for the composite structure after the dielectric structure body 200A and the target component 250 are coupled to each other, the minimum equivalent diameter of the dielectric structure of the composite structure on the projection surface of the surface of the target component 250 through which the radio frequency signal passes is λ/8 or more.

According to another embodiment of the present invention, the dielectric apparatus 200B of FIG. 2B includes a structure body 201 and a positioning component 220. The structure body 201 is formed of a first dielectric material, the structure body 201 includes a chamber 230, and a filler 240 formed of a second dielectric material may fill the chamber 230 when the operating spectrum is required to be switched. The positioning component 220 may be formed of a third dielectric material in an area through which electromagnetic waves pass. The range of dielectric constant values of the first dielectric material, the second dielectric material, and the third dielectric material is greater than 1 and less than or equal to 200,000. The structure body is coupled to the target component 250 by using the positioning component 220. In the transmission state of a radio frequency signal having operating frequency of f and a corresponding wavelength of λ, for the composite structure after the dielectric structure body 200B and the target component 250 are coupled to each other, the minimum equivalent diameter of the dielectric structure of the composite structure on the projection surface of the surface of the target component 250 through which the radio frequency signal passes is λ/8 or more. The dielectric apparatus 200B is different from the dielectric apparatus 200A of the previous embodiment in that the positioning component 220 may be partially interposed between the structure body 201 and the target component 250.

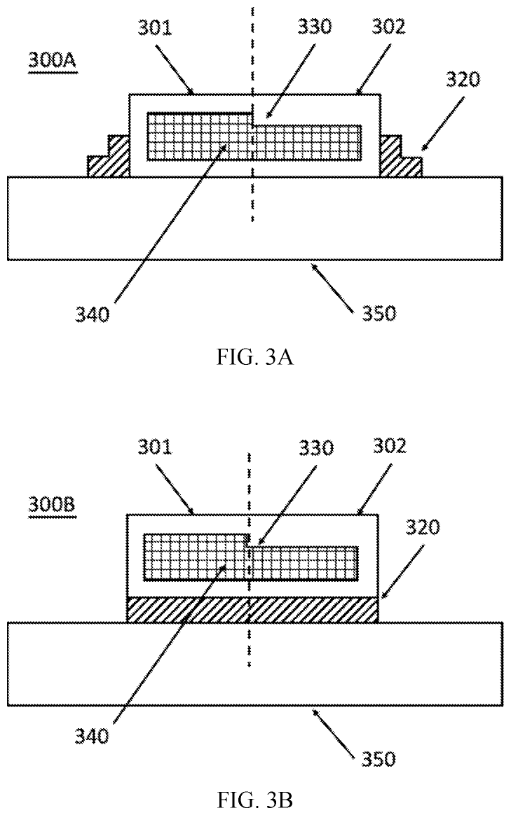

Referring to FIGS. 3A and 3B, FIGS. 3A and 3B are sectional views each showing a dielectric structure according to another embodiment of the present invention. According to another embodiment of the present invention, the dielectric apparatus 300A of FIG. 3A includes a structure body composed of a first block 301 and a second block 302 formed of a first dielectric material, and a positioning component 320, and the structure body may include a chamber 330, in which a filler 340 formed of a second dielectric material may fill the chamber 330 when the operating spectrum is required to be switched. The range of dielectric constant values of the first dielectric material and the second dielectric material is greater than 1 and less than or equal to 200,000. The positioning component 320 couples the structure body to the target component 350, thereby forming a composite structure, so that, for the dielectric structure of the first block 301 in a transmission state of a radio frequency signal having an operating frequency f₁ and a corresponding wavelength λ₁, the minimum equivalent diameter of the dielectric structure of the first block 301 on the projection surface of the surface of the target component 350 through which the radio frequency signal passes is λ₁/8 or more. For the dielectric structure of the second block 302 in a transmission state of a radio frequency signal having an operating frequency f₂ and a corresponding wavelength λ₂, the minimum equivalent diameter of the dielectric structure of the second block 302 on the projection surface of the surface of the target component 350 through which the radio frequency signal passes is λ₂/8 or more.

According to another embodiment of the present invention, the dielectric apparatus 300B of FIG. 3B includes a structure body formed by coupling the first block 301 to the second block 302 formed of a first dielectric material, and a positioning component 320. The structure body includes a chamber 330 with which a filler 340 formed of a second dielectric material is filled when the operating spectrum is required to be switched. The positioning component 320 may be formed of a third dielectric material in an area through which electromagnetic waves pass. The range of dielectric constant values of the first dielectric material, the second dielectric material, and the third dielectric material is greater than 1 and less than or equal to 200,000. The positioning component 320 is used to join the structure body to the target component 350, thereby forming a composite structure, so that, for the dielectric structure of the first block 301 in a transmission state of a radio frequency signal having an operating frequency f₁ and a corresponding wavelength λ₁, the minimum equivalent diameter of the dielectric structure of the first block 301 on the projection surface of the surface of the target component 350 through which the radio frequency signal passes is λ₁/8 or more. For the dielectric structure of the second block 302 in a transmission state of a radio frequency signal having an operating frequency f₂ and a corresponding wavelength λ₂, the minimum equivalent diameter of the dielectric structure of the second block 302 on the projection surface of the surface of the target component 350 through which the radio frequency signal passes is λ₂/8 or more. The dielectric apparatus 300B is different from the dielectric apparatus 300A of the previous embodiment in that the positioning component 320 may be partially interposed between the target component 350 and the structure body including the first block 301 and the second block 302.

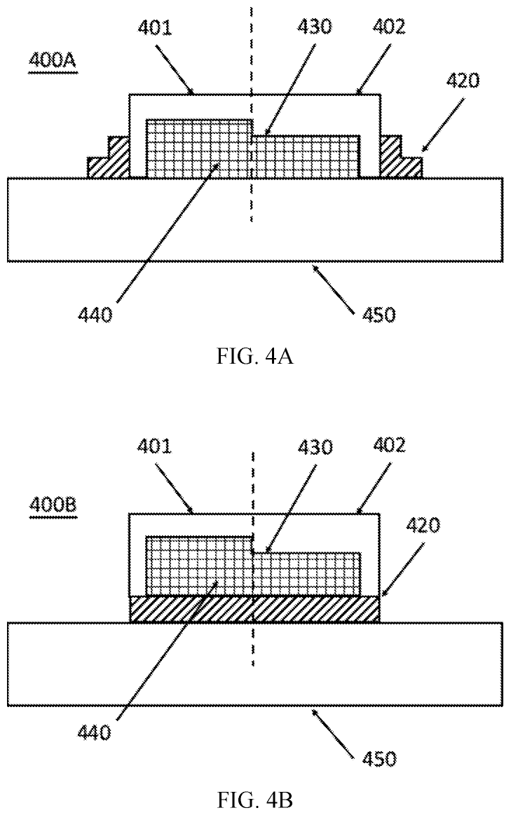

Referring to FIGS. 4A and 4B, FIGS. 4A and 4B are sectional views each showing a dielectric structure according to another embodiment of the present invention. According to another embodiment of the present invention, the dielectric apparatus 400A of FIG. 4A includes a structure body formed by coupling a first block 401 and a second block 402 formed of a first dielectric material, and a positioning component 420. The structure body includes a chamber 430 with which a filler 440 formed of a second dielectric material is filled when the operating spectrum is required to be switched. The range of dielectric constant values of the first dielectric material and the second dielectric material is greater than 1 and less than or equal to 200,000. The positioning component 420 couples the structure body to the target component 450, thereby forming a composite structure. For the dielectric structure of the first block 401 in a transmission state of a radio frequency signal having an operating frequency f₁ and a corresponding wavelength λ₁, the minimum equivalent diameter of the dielectric structure of the first block 401 on the projection surface of the surface of the target component 450 through which the radio frequency signal passes is λ₁/8 or more. For the dielectric structure of the second block 402 in a transmission state of a radio frequency signal having an operating frequency f₂ and a corresponding wavelength λ₂, the minimum equivalent diameter of the dielectric structure of the second block 402 on the projection surface of the surface of the target component 450 through which the radio frequency signal passes is λ₂/8 or more. It is different from the above-described embodiment in that the chamber 430 in this embodiment is arranged in a surface of the structure body, that is, the surface in contact with the target component 450.

According to another embodiment of the present invention, the dielectric apparatus 400B of FIG. 4B includes a structure body formed by coupling a first block 401 and a second block 402 formed of a first dielectric material, and a positioning component 420. The structure body includes a chamber 430 with which a filler 440 formed of a second dielectric material is filled when the operating spectrum is required to be switched. The positioning component 420 may be formed of a third dielectric material in an area through which electromagnetic waves pass. The range of dielectric constant values of the first dielectric material, the second dielectric material, and the third dielectric material is greater than 1 and less than or equal to 200,000. The positioning component 420 couples the structure body to the target component 450, thereby forming a composite structure. For the dielectric structure of the first block 401 In a transmission state of a radio frequency signal having an operating frequency f₁ and a corresponding wavelength λ₁, the minimum equivalent diameter of the dielectric structure of the first block 401 on the projection surface of the surface of the target component 450 through which the radio frequency signal passes is λ₁/8 or more. For the dielectric structure of the second block 402 in a transmission state of a radio frequency signal having an operating frequency f₂ and a corresponding wavelength λ₂, the minimum equivalent diameter of the dielectric structure of the second block 402 on the projection surface of the surface of the target component 450 through which the radio frequency signal passes is λ₂/8 or more. The dielectric apparatus 400B is different from the dielectric apparatus 400A of the previous embodiment in that the positioning component 420 may be partially interposed between the target component 450 and the structure body including the first block 401 and the second block 402. The chamber 430 is provided on the surface of the structure body, and comes into contact with a part of the positioning component 420.

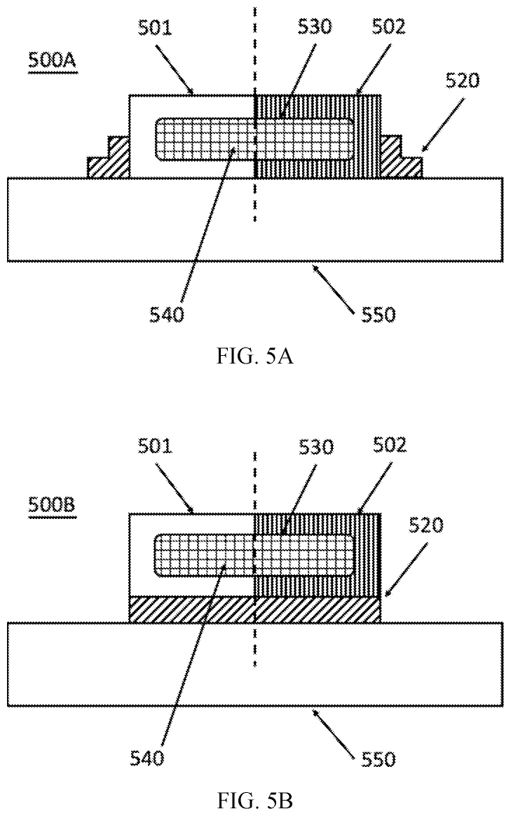

Referring to FIGS. 5A and 5B, FIGS. 5A and 5B are sectional views each showing a dielectric structure according to another embodiment of the present invention. According to another embodiment of the present invention, the dielectric apparatus 500A of FIG. 5A includes a structure body formed by coupling a first block 501 formed of a first dielectric material and a second block 502 formed of a second dielectric material, and a positioning component 520. The structure body includes a chamber 530 with which a filler 540 formed of a third dielectric material is filled when the operating spectrum is required to be switched. The range of dielectric constant values of the first dielectric material, the second dielectric material, and the third dielectric material is greater than 1 and less than or equal to 200,000. The positioning component 520 couples the structure body to the target component 550, thereby forming a composite structure, so that, for the dielectric structure of the first block 501 in a transmission state of a radio frequency signal having an operating frequency f₁ and a corresponding wavelength λ₁, the minimum equivalent diameter of the dielectric structure of the first block 501 on the projection surface of the surface of the target component 550 through which the radio frequency signal passes is λ₁/8 or more. For the dielectric structure of the second block 502 in a transmission state of a radio frequency signal having an operating frequency f₂ and a corresponding wavelength λ₂, the minimum equivalent diameter of the dielectric structure of the second block 502 on the projection surface of the surface of the target component 550 through which the radio frequency signal passes is λ₂/8 or more. It is different from the above-described embodiment in that the chamber 530 in this embodiment is arranged inside the structure body, but does not come into contact with the target component 550.

According to another embodiment of the present invention, the dielectric apparatus 500B of FIG. 5B includes a structure body formed by coupling a first block 501 formed of a first dielectric material and a second block 502 formed of a second dielectric material, and a positioning component 520. The structure body includes a chamber 530 with which a filler 540 formed of a third dielectric material is filled when the operating spectrum is required to be switched. The positioning component 520 may be formed of a fourth dielectric material in an area through which electromagnetic waves pass. The range of dielectric constant values of the first dielectric material, the second dielectric material, the third dielectric material, and the fourth dielectric material is greater than 1 and less than or equal to 200,000. The positioning component 520 couples the structure body to the target component 550, thereby forming a composite structure, so that, for the dielectric structure of the first block 501 in a transmission state of a radio frequency signal having an operating frequency f₁ and a corresponding wavelength λ₁, the minimum equivalent diameter of the dielectric structure of the first block 501 on the projection surface of the surface of the target component 550 through which the radio frequency signal passes is λ₁/8 or more. For the dielectric structure of the second block 502 in a transmission state of a radio frequency signal having an operating frequency f₂ and a corresponding wavelength λ₂, the minimum equivalent diameter of the dielectric structure of the second block 502 on the projection surface of the surface of the target component 550 through which the radio frequency signal passes is λ₂/8 or more. The dielectric apparatus 500B is different from the dielectric apparatus 500A of the previous embodiment in that the positioning component 520 may be partially interposed between the target component 550 and the structure body including the first block 501 and the second block 502.

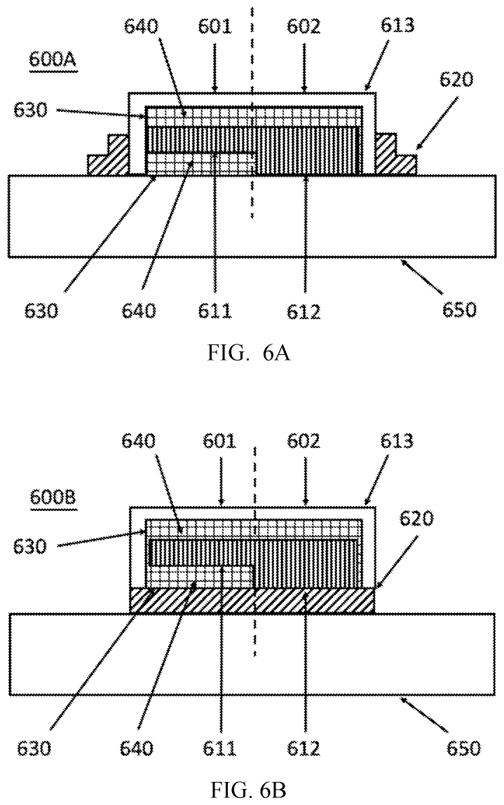

Referring to FIGS. 6A and 6B, FIGS. 6A and 6B are sectional views each showing a dielectric structure according to another embodiment of the present invention. According to another embodiment of the present invention, the dielectric apparatus 600A of FIG. 6A includes a structure body formed by coupling a first block 601 and a second block 602, and a positioning component 620. The first block 601 is a multilayer dielectric material structural layer composed of a first dielectric material structure 613, a chamber 630, a second dielectric material structure 611, and a filler 640 formed of a third dielectric material for filler the chamber 630 when spectrum is required to be switched. In addition, the second block 602 is a multilayer dielectric material structural layer composed of a first dielectric material structure 613, a chamber 630, a second dielectric material structure 611, and a filler 640 formed of a third dielectric material for filler the chamber 630 when spectrum is required to be switched. The difference between the first block 601 and the second block 602 is the arrangement structures between the second dielectric material structure 611 in the first block 601 and the second dielectric material structure 612 in the second block 602 are different, and the space ratios occupied in the chamber 630 are different. The range of dielectric constant values of the first dielectric material, the second dielectric material, and the third dielectric material is greater than 1 and less than or equal to 200,000. The positioning component 620 couples the structure body to the target component 650, thereby forming a composite structure, so that, for the dielectric structure of the first block 601 in a transmission state of a radio frequency signal having an operating frequency f₁ and a corresponding wavelength λ₁, the minimum equivalent diameter of the dielectric structure of the first block 601 on the projection surface of the surface of the target component 650 through which the radio frequency signal passes is λ₁/8 or more. For the dielectric structure of the second block 602 in a transmission state of a radio frequency signal having an operating frequency f₂ and a corresponding wavelength λ₂, the minimum equivalent diameter of the dielectric structure of the second block 602 on the projection surface of the surface of the target component 650 through which the radio frequency signal passes is λ₂/8 or more.

According to another embodiment of the present invention, the dielectric apparatus 600B of FIG. 6B includes a structure body formed by coupling a first block 601 and a second block 602, and a positioning component 620. The first block 601 is a multilayer dielectric material structural layer composed of a first dielectric material structure 613, a chamber 630, a second dielectric material structure 611, and a filler 640 formed of a third dielectric material for filler the chamber 630 when spectrum is required to be switched. The second block 602 is a multilayer dielectric material structural layer composed of a first dielectric material structure 613, a chamber 630, a second dielectric material structure 611, and a filler 640 formed of a third dielectric material for filler the chamber 630 when spectrum is required to be switched. The difference between the first block 601 and the second block 602 is the arrangement structures between the second dielectric material structure 611 in the first block 601 and the second dielectric material structure 612 in the second block 602 are different, and the space ratios occupied in the chamber 630 are different. The positioning component 620 may be formed of a fourth dielectric material in an area through which electromagnetic waves pass. The range of dielectric constant values of the first dielectric material, the second dielectric material, the third dielectric material, and the fourth dielectric material is greater than 1 and less than or equal to 200,000. The positioning component 620 couples the structure body to the target component 650, thereby forming a composite structure, so that, for the dielectric structure of the first block 601 in a transmission state of a radio frequency signal having an operating frequency f₁ and a corresponding wavelength λ₁, the minimum equivalent diameter of the dielectric structure of the first block 601 on the projection surface of the surface of the target component 650 through which the radio frequency signal passes is λ₁/8 or more. For the dielectric structure of the second block 602 in a transmission state of a radio frequency signal having an operating frequency f₂ and a corresponding wavelength λ₂, the minimum equivalent diameter of the dielectric structure of the second block 602 on the projection surface of the surface of the target component 650 through which the radio frequency signal passes is λ₂/8 or more. The dielectric apparatus 600B is different from the dielectric apparatus 600A of the previous embodiment in that the positioning component 620 may be partially interposed between the target component 650 and the structure body including the first block 601 and the second block 602.

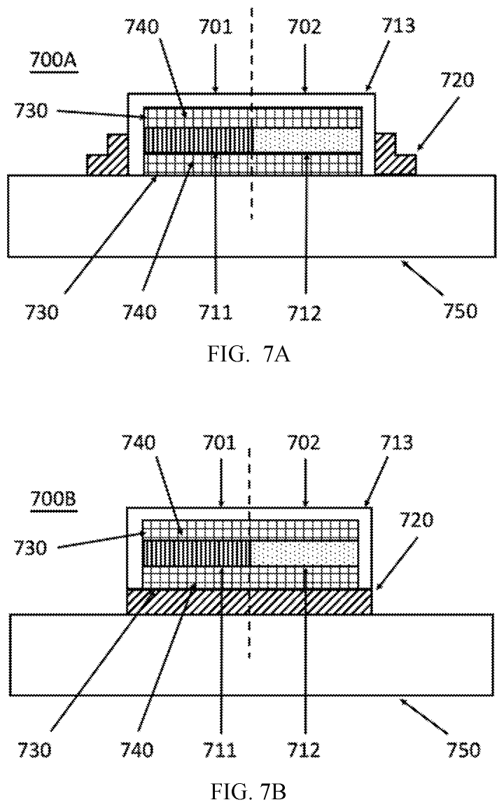

Referring to FIGS. 7A and 7B, FIGS. 7A and 7B are sectional views each showing a dielectric structure according to another embodiment of the present invention. According to another embodiment of the present invention, the dielectric apparatus 700A of FIG. 7A includes a structure body formed by coupling a first block 701 and a second block 702, and a positioning component 720. The first block 701 is a multilayer dielectric material structural layer composed of a first dielectric material structure 713, a chamber 730, a second dielectric material structure 711, and a filler 740 formed of a fourth dielectric material for filler the chamber 730 when spectrum is required to be switched. The second first block 702 is a multilayer dielectric material structural layer composed of a first dielectric material structure 713, a chamber 730, a third dielectric material structure 712, and a filler 740 formed of a fourth dielectric material for filler the chamber 730 when spectrum is required to be switched. The difference between the first block 701 and the second block 702 is that the second dielectric material structure 711 and the third dielectric material structure 712 have materials different from each other. The range of dielectric constant values of the first dielectric material, the second dielectric material, the third dielectric material, and the fourth dielectric material is greater than 1 and less than or equal to 200,000. The positioning component 720 couples the structure body to the target component 750, thereby forming a composite structure, so that, for the dielectric structure of the first block 701 in a transmission state of a radio frequency signal having an operating frequency f₁ and a corresponding wavelength λ₁, the minimum equivalent diameter of the dielectric structure of the first block 701 on the projection surface of the surface of the target component 750 through which the radio frequency signal passes is λ₁/8 or more. For the dielectric structure of the second block 702 in a transmission state of a radio frequency signal having an operating frequency f₂ and a corresponding wavelength λ₂, the minimum equivalent diameter of the dielectric structure of the second block 702 on the projection surface of the surface of the target component 750 through which the radio frequency signal passes is λ₂/8 or more.

According to another embodiment of the present invention, the dielectric apparatus 700B of FIG. 7B includes a structure body formed by coupling a first block 701 and a second block 702, and a positioning component 720. The first block 701 is a multilayer dielectric material structural layer composed of a first dielectric material structure 713, a chamber 730, a second dielectric material structure 711, and a filler 740 formed of a fourth dielectric material for filler the chamber 730 when spectrum is required to be switched. The second first block 702 is a multilayer dielectric material structural layer composed of a first dielectric material structure 713, a chamber 730, a third dielectric material structure 712, and a filler 740 formed of a fourth dielectric material for filler the chamber 730 when spectrum is required to be switched. The difference between the first block 701 and the second block 702 is that the second dielectric material structure 711 and the third dielectric material structure 712 have materials different from each other. The positioning component 720 may be formed of a fifth dielectric material in an area through which electromagnetic waves pass. The range of dielectric constant values of the first dielectric material, the second dielectric material, the third dielectric material, the fourth dielectric material, and the fifth dielectric material is greater than 1 and less than or equal to 200,000. The positioning component 720 couples the structure body to the target component 750, thereby forming a composite structure, so that, for the dielectric structure of the first block 701 in a transmission state of a radio frequency signal having an operating frequency f₁ and a corresponding wavelength λ₁, the minimum equivalent diameter of the dielectric structure of the first block 701 on the projection surface of the surface of the target component 750 through which the radio frequency signal passes is λ₁/8 or more. For the dielectric structure of the second block 702 in a transmission state of a radio frequency signal having an operating frequency f₂ and a corresponding wavelength λ₂, the minimum equivalent diameter of the dielectric structure of the second block 702 on the projection surface of the surface of the target component 750 through which the radio frequency signal passes is λ₂/8 or more. The dielectric apparatus 700B is different from the dielectric apparatus 700A of the previous embodiment in that the positioning component 720 may be partially interposed between the target component 750 and the structure body including the first block 701 and the second block 702.

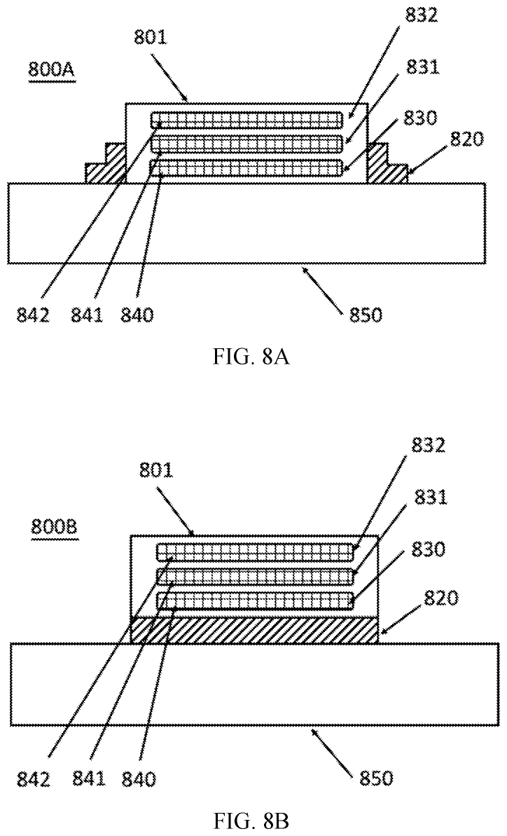

Referring to FIGS. 8A and 8B, FIGS. 8A and 8B are sectional views each showing a dielectric structure according to another embodiment of the present invention. According to another embodiment of the present invention, the dielectric apparatus 800A of FIG. 8A includes a structure body 801 and a positioning component 820. The structure body 801 is formed of a first dielectric material, and the structure body 801 includes a plurality of cavities. In the embodiment, the structure body 801 includes a first chamber 830, a second chamber 831 and a third chamber 832, and may be filled with a first filler 840, a second filler 841, and a third filler 842 formed of a dielectric material when spectrum is required to be switched. The first dielectric material and the filler dielectric material have dielectric constant values in a range of greater than 1 and less than or equal to 200,000, and each filler dielectric material may be a material having a different dielectric constant value. The positioning component 820 couples the structure body to the target component 850, thereby forming a composite structure, so that, for the dielectric structure corresponding to the composite structure in a transmission state of a radio frequency signal having an operating frequency f and a corresponding wavelength k, the minimum equivalent diameter of the dielectric structure on the projection surface of the surface of the target component 850 through which the radio frequency signal passes is λ/8 or more.

According to another embodiment of the present invention, the dielectric apparatus 800B of FIG. 8B includes a structure body 801 and a positioning component 820. The structure body 801 is formed of a first dielectric material, and the structure body 801 includes a plurality of cavities. In the embodiment, the structure body 801 includes a first chamber 830, a second chamber 831 and a third chamber 832, and may be filled with a first filler 840, a second filler 841, and a third filler 842 formed of a dielectric material when spectrum is required to be switched. The positioning component 820 may be formed of a second dielectric material in an area through which electromagnetic waves pass. The range of values of dielectric constants of the first dielectric material, the second dielectric material, and the filler dielectric material is greater than 1 and less than or equal to 200,000. Each filler dielectric material may be a material having a different dielectric constant value. The positioning component 820 couples the structure body to the target component 850, thereby forming a composite structure, so that, for the dielectric structure corresponding to the composite structure in a transmission state of a radio frequency signal having an operating frequency f and a corresponding wavelength λ, the minimum equivalent diameter of the dielectric structure on the projection surface of the surface of the target component 850 through which the radio frequency signal passes is λ/8 or more. The dielectric apparatus 800B is different from the dielectric apparatus 800A of the previous embodiment in that the positioning component 820 may be partially interposed between the structure body 801 and the target component 850.

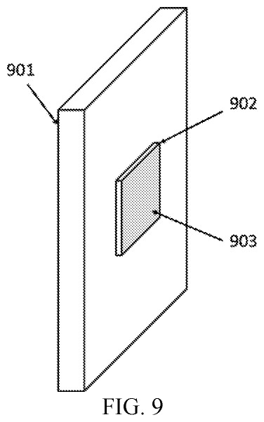

FIG. 9 is a schematic diagram showing a state in which a target component 901 according to the embodiment of the present invention is coupled to a structure 903 through a positioning component 902. The aforementioned target component 901 may be, for example, a building component formed of glass, cement, wood, ceramic, plastic, or other dielectric materials. However, the present invention is not limited thereto. The target component 901 may be any component capable of improving the transmittance of radio frequency signals, if necessary.

Besides, since the dielectric constant varies with the operating frequency, the specific type of material is adjusted to correspond to the dielectric constant value of the target component within the operating frequency spectrum. Representative materials usable as the material of the apparatus structure itself are as follows, but the present disclosure is not limited to the materials listed below. The material includes as follows. Materials with a low dielectric constant: PTFE, PE, PC, PVC, acrylic, PU, epoxy, silicone, and the like; Materials with an intermediate dielectric constant: quartz, glass, aluminum oxide crystals and ceramics, aluminum nitride crystals and ceramics, magnesium oxide crystals and ceramics, silicon carbide crystals and ceramics, zirconium oxide crystals and ceramics, and the like; and Materials with a high dielectric constant: titanium oxide crystals and ceramics, barium titanate polymer composite materials, and the like. Liquid or gaseous dielectric materials may also be used for the dielectric material for filler the chamber, in addition to using the above-mentioned solid material for filler the chamber in powder form or in a preformed structural form, for example, solid powder or a molded filler. Listed below are gaseous and liquid dielectric materials usable to fill the chamber, but the present disclosure is not limited to these materials. The gaseous material includes air, nitrogen, helium, argon, oxygen, hydrogen, water vapor, carbon monoxide, carbon dioxide, vaporized hydrocarbons, vaporized nitrogen oxides and mixed gases and the like; and the liquid material includes water, alcohols, salt-containing aqueous solutions, alcoholic solutions, and solutions prepared from other soluble solutes and solvents, and the like.

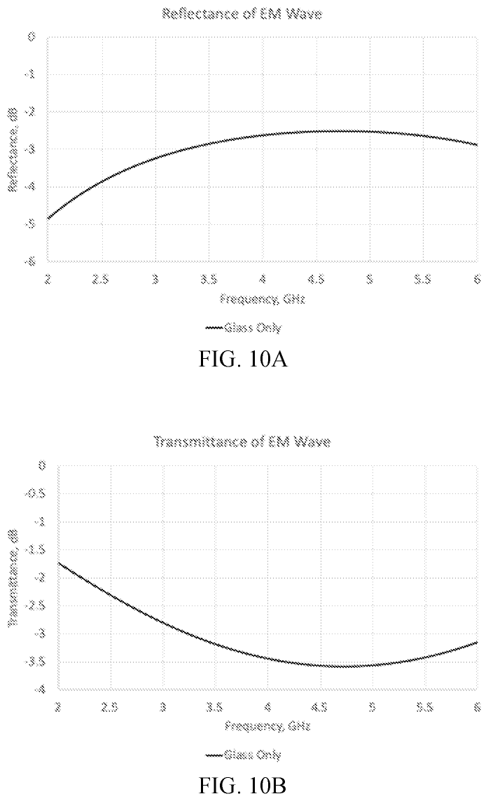

Referring to FIGS. FIGS. 10A and 10B, graphs show the reflectance and transmittance when electromagnetic waves of 2 GHz to 6 GHz pass through glass with a thickness of 6 mm and a dielectric constant of 7. As shown in the drawings, the reflectance is −2.838 dB, −2.612 dB and −2.515 dB at operating frequencies of 3.5 GHz, 4.0 GHz and 5.0 GHz, respectively; and the transmittance decreases to −3.190 dB, −3.449 dB and −3.570 dB due to the reflection. In the evaluation condition of reflectance −10 dB bandwidth, the bandwidths of 3.5 GHz, 4.0 GHz and 5.0 GHz are zero.

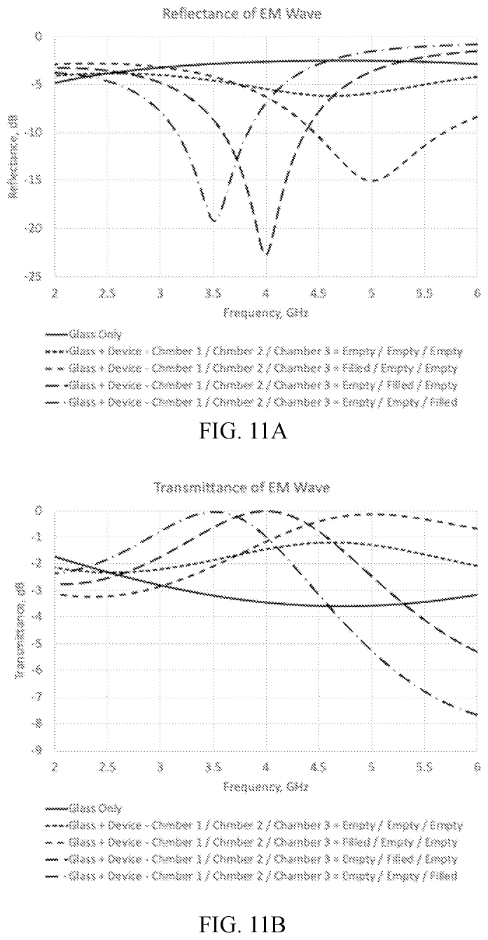

Referring to FIGS. 11A and 11B, the graphs indicate the reflectance and transmittance when electromagnetic waves of 2 GHz to 6 GHz pass through glass having a thickness of 6 mm and a dielectric constant of 7 and the dielectric apparatus, the device, shown in FIG. 8A is coupled thereon. The material for fabricating the dielectric apparatus structure is a polymer material having a dielectric constant value of 2.5, and the structure body contains three cavities. The structure and thickness of each layer in a section of the structure body, sequentially from the bottom layer to the top layer of the coupled glass, are as follows: bottom layer (1.80 mm)/first chamber (0.22 mm)/spacer (3.00 mm)/second chamber (0.22 mm)/spacer (2.50 mm)/third chamber (0.22 mm)/top layer (2.50 mm). The frequency is switched by filler each chamber with water having a dielectric constant value of 80 as needed. According to the simulation when the chamber is not filled, the reflectance of 3.5 GHz, 4.0 GHz and 5.0 GHz is −4.586 dB, −5.465 dB and −5.895 dB, and the transmittance is −1.856 dB, −1.451 dB and −1.292 dB, respectively. In other words, it can be seen that the transmittance increases at 3.5 GHz, 4.0 GHz, and 5.0 GHz for electromagnetic waves after the apparatus is coupled to the glass. However, the bandwidth of each operating frequency still appears as zero at −10 dB reflectance. Accordingly, it is still not suitable for use as a normal signal. In the case of operating frequency of 5.0 GHz, and when only the first chamber is filled with water, the reflectance is −15.031 dB, the transmittance is −0.139 dB, and the bandwidth is 1.230 GHz; In the case of operating frequency of 4.0 GHz, and when only the second chamber is filled with water, the reflectance is −22.745 dB, the transmittance is −0.023 dB, and the bandwidth is 0.781 GHz; In the case of operating frequency of 3.5 GHz, and when only the third chamber is filled with water, the reflectance is −19.196 dB, the transmittance is −0.053 dB, and the bandwidth is 0.6773 GHz. Thus, it can be seen that filler different cavities with water can significantly improve the transmittance of electromagnetic waves at certain operating frequencies. Therefore, when the present method is applied, the operating frequency can be switched and the application requirements of high-frequency transmission can be implemented.

The admittance of the corresponding operating spectrum is analyzed through a structure body made of a dielectric material, so that the composite structure formed by coupling the dielectric apparatus according to the present disclosure to the building component may adjust the admittance value in block units, and accordingly, the transmittance of the composite structure can be improved in operating spectrum signals of different frequency bandwidths. In addition, the material filled in the chamber is adjusted according to the required signal, so that the purpose of switching the operating spectrum can be achieved.

The embodiments of the present disclosure are described above with reference to the accompanying drawings, but the present disclosure is not limited to the aforementioned specific embodiments. The specific implementation as mentioned above is merely indicative rather than restrictive. Equivalent modifications or changes made by a person of ordinary skill in the art under the implication of the present disclosure, without departing from the spirit and scope of the present disclosure, shall be included in the following claims.

What is claimed is:

1. A dielectric apparatus for building components to switch an operating frequency of a radio frequency signal passing through the building components and increase a transmittance and a transmission bandwidth of the radio frequency signal, the dielectric apparatus comprising:
a structure body formed of a dielectric material, and having a chamber;
a filler formed of a dielectric material and filled in the chamber; and
a positioning component configured to couple the structure body to a target component, wherein
a dielectric constant value of each dielectric material included in an area through which the radio frequency signal passes in the structure body, the filler, and the positioning component is greater than 1 and less than or equal to 200,000,
the positioning component couples the structure body formed of a dielectric material to the target component, thereby forming a composite structure correspondingly having the operating frequency, and
a minimum equivalent diameter of a dielectric structure corresponding to the composite structure at a projection surface of a target component through which the radio frequency signals pass is at least ⅛ of the operating wavelength corresponding to the operating frequency.

2. The dielectric apparatus of claim 1, wherein the structure includes a plurality of blocks formed of dielectric materials, and each of the blocks independently has a corresponding specific operating frequency.

3. The dielectric apparatus of claim 1, wherein the positioning component includes a dielectric material layer, and a dielectric material constituting the dielectric material layer has an equivalent dielectric constant value in a range of greater than 1 and less than or equal to 200,000.

4. The dielectric apparatus of claim 1, wherein the positioning component is partially interposed between the structure body and the target component.

5. The dielectric apparatus of claim 1, wherein the filler includes a solid powder material or a molded filler.

6. The dielectric apparatus of claim 1, wherein the filler includes a fluid filler in a liquid form or a gaseous form.

7. The dielectric apparatus of claim 1, wherein a state of the filler in the chamber is changed in a placement, injection, withdrawal or extraction manner, so that the filler changes the operating frequency when electromagnetic waves of the radio frequency signal pass through.

8. The dielectric apparatus of claim 1, further comprising: a void area.

9. The dielectric apparatus of claim 8, wherein the void area is interposed between the structure body and the target component.

10. The dielectric apparatus of claim 8, wherein the void area is provided inside the structure body without coming into contact with the target component.

11. A method of arranging a dielectric apparatus applied to building components to switch an operating frequency of a radio frequency signal passing through the building components and increase a transmittance and a transmission bandwidth of the radio frequency signal, the method comprising:
coupling a structure body to a target component by a positioning component, wherein the structure body is formed of a dielectric material and the structure body includes a chamber, a filler formed of a dielectric material fills the chamber,
the positioning component is formed of a dielectric material in an area through which the radio frequency signal passes,
the range of a dielectric constant value of each dielectric material is greater than 1 and less than or equal to 200,000,
the positioning component couples the structure body formed of a dielectric material to the target component, thereby forming a composite structure correspondingly having the operating frequency, and
a minimum equivalent diameter of a dielectric structure corresponding to the composite structure at a projection surface of a target component through which the radio frequency signals pass is at least ⅛ of the operating wavelength corresponding to the operating frequency.

12. The method of claim 11, further comprising:
providing a void area in the dielectric apparatus.
